(19) United States
(12) Patent Application Publication
(10) Pub. No.: US 2007/0170959 A1
(43) Pub. Date: Jul. 26, 2007

(54) Phase detector

(76) Inventor: Alessandro Minzoni, Morrisville, NC (US)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/338,042

(22) Filed: Jan. 24, 2006

(51) Int. Cl. H03B 1/00

(52) U.S. Cl. 327/112

(57) ABSTRACT

A phase detector includes a first circuit, a second circuit, and a third circuit. The first circuit is configured to provide a first signal in response to a feedback signal and a clock signal. The second circuit is configured to provide a second signal in response to the clock signal and an inverted clock signal. The third circuit is configured to provide a third signal indicating whether the clock signal leads the feedback signal and a fourth signal indicating whether the feedback signal leads the clock signal in response to the first signal and the second signal.

### BACKGROUND

Phase detectors are used in a variety of circuits, such as delay locked loops (DLLs), duty cycle correctors, and other circuits in which the phase between two signals is used to adjust some portion of a circuit. Phase detectors are typically used in memories such as Random Access Memory (RAM), Dynamic Random Access Memory (DRAM), Synchronous Dynamic Random Access Memory (SDRAM), and Double Data Rate SDRAM (DDR-SDRAM).

One type of phase detector receives two input signals and provides two output signals. The phase detector evaluates the phase difference between the two input signals to provide the two output signals. If the first input signal leads the second input signal, the phase detector activates the first output signal and deactivates the second output signal. If the first input signal lags the second input signal, the phase detector activates the second output signal and deactivates the first output signal. The first output signal can be used to adjust a circuit to increase a delay of the first input signal or decrease a delay of the second input signal to bring the phase of the first input signal closer to the phase of the second input signal. The second output signal can be used to adjust the circuit to decrease the delay of the first input signal or increase the delay of the second input signal to bring the phase of the first input signal closer to the phase of the second input signal.

Typical phase detectors may produce errors when operating at high frequencies. When the phase difference between the two input signals is small, a race condition between the two input signals through the phase detector may lead to incorrect output signals.

### SUMMARY

One embodiment of the present invention provides a phase detector. The phase detector includes a first circuit, a second circuit, and a third circuit. The first circuit is configured to provide a first signal in response to a feedback signal and a clock signal. The second circuit is configured to provide a second signal in response to the clock signal and an inverted clock signal. The third circuit is configured to provide a third signal indicating whether the clock signal leads the feedback signal and a fourth signal indicating whether the feedback signal leads the clock signal in response to the first signal and the second signal.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an electronic system.

FIG. 2 is a schematic diagram illustrating one embodiment of a phase detector.

FIG. 3 is a timing diagram illustrating one embodiment of the timing of signals for the phase detector.

FIG. 4 is a timing diagram illustrating another embodiment of the timing of signals for the phase detector.

### DETAILED DESCRIPTION

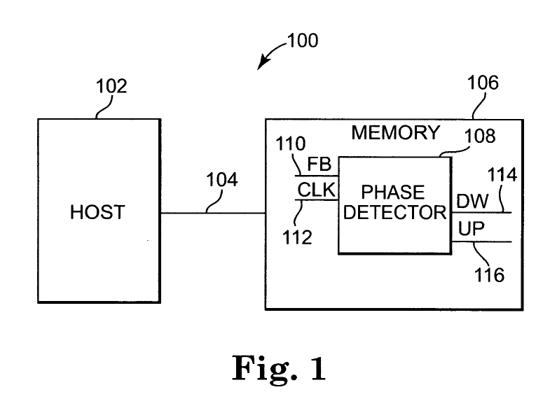

FIG. 1 is a block diagram illustrating one embodiment of an electronic system 100. Electronic system 100 includes a host 102 and a memory circuit 106. Host 102 is electrically coupled to memory circuit 106 through memory communications path 104. Host 102 is any suitable electronic host, such as a computer system including a microprocessor or a microcontroller. Memory circuit 106 is any suitable memory, such as a memory that utilizes a clock signal to operate. In one embodiment, memory circuit 106 comprises a random access memory, such as a Dynamic Random Access Memory (DRAM), Synchronous Dynamic Random Access Memory (SDRAM), or Double Data Rate Synchronous Dynamic Random Access Memory (DDR-SDRAM).

Memory circuit 106 includes a phase detector 108 that receives a feedback (FB) signal on FB signal path 110 and a clock (CLK) signal on CLK signal path 112. In one embodiment, phase detector 108 receives an external clock signal on CLK signal path 112 through memory communications path 104. In other embodiments, phase detector 108 receives an external clock signal or internal clock signal on CLK signal path 112 from any suitable device, such as a dedicated clock circuit that is located inside or outside memory circuit 106.

Phase detector 108 provides the down (DW) signal on DW signal path 114 and the up (UP) signal on UP signal path 116. Phase detector 108 determines the phase difference between the FB signal on FB signal path 110 and the CLK signal on CLK signal path 112 to provide the DW signal on DW signal path 114 and the UP signal on UP signal path 116. In response to the CLK signal leading the FB signal, phase detector 108 activates the DW signal and deactivates the UP signal. In response to the FB signal leading the CLK signal, phase detector 108 activates the UP signal and deactivates the DW signal. The UP signal and the DW signal can be provided to another circuit and used as control signals to adjust a delay of the CLK signal or a delay of the FB signal to bring the phase of the FB signal closer to the phase of the CLK signal.

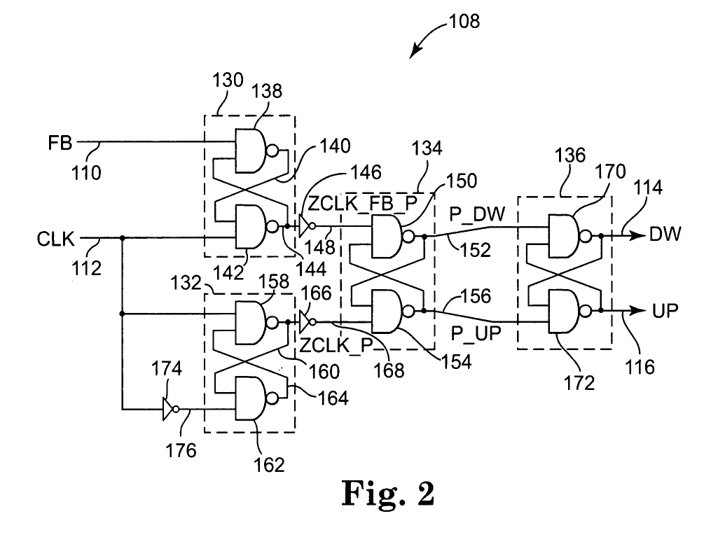

FIG. 2 is a schematic diagram illustrating one embodiment of phase detector 108. Phase detector 108 includes NAND gates 138, 142, 150, 154, 158, 162, 170, and 172 and inverters 146, 166, and 174. A first input of NAND gate 138 receives the FB signal on FB signal path 110. The output of NAND gate 138 is electrically coupled to a first input of NAND gate 142 through signal path 140. A second input of NAND gate 142, a first input of NAND gate 158, and the input of inverter 174 receive the CLK signal on CLK signal path 112. The output of NAND gate 142 is electrically coupled to a second input of NAND gate 138 and the input of inverter 146 through signal path 144.

A second input of NAND gate 158 is electrically coupled to the output of NAND gate 162 through signal path 164. The output of NAND gate 158 is electrically coupled to a first input of NAND gate 162 and to the input of inverter 166 though signal path 160. The output of inverter 174 is electrically coupled to a second input of NAND gate 162 through signal path 176.

The output of inverter 146 is electrically coupled to a first input of NAND gate 150 through ZCLK_FB_P signal path 148. The output of inverter 166 is electrically coupled to a first input of NAND gate 154 through ZCLK_P signal path 168. The output of NAND gate 150 is electrically coupled to a second input of NAND gate 154 and a first input of NAND gate 170 through pulse down (P_DW) signal path 152. The output of NAND gate 154 is electrically coupled to a second input of NAND gate 150 and a first input of NAND gate 172 through pulse up (P_UP) signal path 156. The output of NAND gate 170 provides the DW signal and is electrically coupled to a second input of NAND gate 172 through DW signal path 114. The output of NAND gate 172 provides the UP signal and is electrically coupled to a second input of NAND gate 170 through UP signal path 116.

NAND gates 138 and 142 provide a first flip-flop indicated at 130. NAND gates 158 and 162 provide a second flip-flop indicated at 132. NAND gates 150 and 154 provide a third flip-flop indicated at 134. NAND gates 170 and 172 provide a fourth flip-flop indicated at 136.

In response to a logic high FB signal on FB signal path 110 and the logic high signal on signal path 144, NAND gate 138 outputs a logic low signal on signal path 140. In response to a logic low FB signal on FB signal path 110 or a logic low signal on signal path 144, NAND gate 138 outputs a logic high signal on signal path 140. In response to a logic high CLK signal on CLK signal path 112 and a logic high signal on signal path 140, NAND gate 142 outputs a logic low signal on signal path 144. In response to a logic low CLK signal on CLK signal path 112 or a logic low signal on signal path 140, NAND gate 142 outputs a logic high signal on signal path 144. Inverter 146 inverts the signal on signal path 144 to provide the ZCLK_FB_P signal on ZCLK_FB_P signal path 148.

In response to a logic high CLK signal on CLK signal path 112 and a logic high signal on signal path 164, NAND gate 158 outputs a logic low signal on signal path 160. In response to a logic low CLK signal on CLK signal path 112 or a logic low signal on signal path 164, NAND gate 158 outputs a logic high signal on signal path 160. Inverter 174 inverts the CLK signal on CLK signal path 112 to provide the signal on signal path 176. In response to a logic high signal on signal path 160 and a logic high signal on signal path 176, NAND gate 162 outputs a logic low signal on signal path 164. In response to a logic low signal on signal path 160 or a logic low signal on signal path 176, NAND gate 162 outputs a logic high signal on signal path 164. Inverter 166 inverts the signal on signal path 160 to provide the ZCLK_P signal on ZCLK_P signal path 168.

In response to a logic high ZCLK_FB_P signal on ZCLK_FB_P signal path 148 and a logic high P_UP signal on P_UP signal path 156, NAND gate 150 outputs a logic low P_DW signal on P_DW signal path 152. In response to a logic low ZCLK_FB_P signal on ZCLK_FB_P signal path 148 or a logic low P_UP signal on P_UP signal path 156, NAND gate 150 outputs a logic high P_DW signal on P_DW signal path 152. In response to a logic high P_DW signal on P_DW signal path 152 and a logic high ZCLK_P signal on ZCLK_P signal path 168, NAND gate 154 outputs a logic low P_UP signal on P_UP signal path 156. In response to a logic low P_DW signal on P_DW signal path 152 or a logic low ZCLK_P signal on ZCLK_P signal path 168, NAND gate 154 outputs a logic high P_UP signal on P_UP signal path 156.

In response to a logic high P_DW signal on P_DW signal path 152 and a logic high UP signal on UP signal path 116, NAND gate 170 outputs a logic low DW signal on DW signal path 114. In response to a logic low P_DW signal on P_DW signal path 152 or a logic low UP signal on UP signal path 116, NAND gate 170 outputs a logic high DW signal on DW signal path 114. In response to a logic high DW signal on DW signal path 114 and a logic high P_UP signal on P_UP signal path 156, NAND gate 172 outputs a logic low UP signal on UP signal path 116. In response to a logic low DW signal on DW signal path 114 or a logic low P_UP signal on P_UP signal path 156, NAND gate 172 outputs a logic high UP signal on UP signal path 116.

In operation, with the rising edge of the CLK signal leading the rising edge of the FB signal, flip-flop 130 outputs a logic low signal on signal path 144 in response to the rising edge of the CLK signal. With the falling edge of the FB signal leading the falling edge of the CLK signal, flip-flop 130 outputs a logic low signal on signal path 144 in response to the falling edge of the FB signal. In response to a logic low signal on signal path 144, inverter 146 provides a logic high ZCLK_FB_P signal.

Flip-flop 132 outputs a logic low signal on signal path 160 in response to the rising edge of the CLK signal. In response to a logic low signal on signal path 160, inverter 166 provides a logic high ZCLK_P signal. The rising edge of the ZCLK_P signal is delayed from the rising edge of the CLK signal by at least one gate delay.

With the rising edge of the ZCLK_FB_P signal leading the rising edge of the ZCLK_P signal, flip-flop 134 outputs a logic low P_DW signal in response to the rising edge of the ZCLK_FB_P signal. With the rising edge of the ZCLK_P signal leading the rising edge of the ZCLK_FB_P signal, flip-flop 134 outputs a logic low P_UP signal in response to the rising edge of the ZCLK_P signal. In response to a logic low P_DW signal, flip-flop 136 outputs a logic high DW signal and a logic low UP signal. In response to a logic low P_UP signal, flip-flop 136 outputs a logic low DW signal and a logic high UP signal.

In response to the CLK signal leading the FB signal, the ZCLK_FB_P signal transitions to logic high before the ZCLK_P signal transitions to logic high. In response to the ZCLK_FB_P signal transitioning to logic high before the ZCLK_P signal, the P_DW signal transitions to logic low. In response to the P_DW signal transitioning to logic low, the DW signal transitions to logic high. In response to the FB signal leading the CLK signal, the ZCLK_P signal transitions to logic high before the ZCLK_FB_P signal transitions to logic high. In response to the ZCLK_P signal transitioning to logic high before the ZCLK_FB_P signal, the P_UP signal transitions to logic low. In response to the P_UP signal transitioning to logic low, the UP signal transitions to logic high.

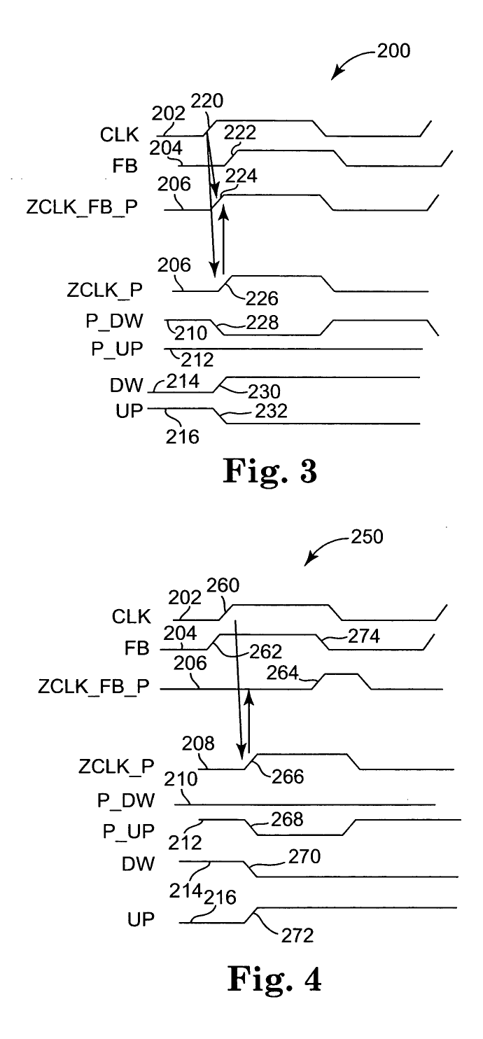

FIG. 3 is a timing diagram 200 illustrating one embodiment of the timing of signals for phase detector 108. Timing diagram 200 includes CLK signal 202 on CLK signal path 112, FB signal 204 on FB signal path 110, ZCLK_FB_P signal 206 on ZCLK_FB_P signal path 148, ZCLK_P signal 208 on ZCLK_P signal path 168, P_DW signal 210 on P_DW signal path 152, P_UP signal 212 on P_UP signal path 156, DW signal 214 on DW signal path 114, and UP signal 216 on UP signal path 116.

Rising edge 220 of CLK signal 202 leads rising edge 222 of FB signal 204. In response to rising edge 220 of CLK signal 202, flip-flop 138 and inverter 146 provide rising edge 224 of ZCLK_FB_P signal 206. Also in response to rising edge 220 of CLK signal 202, inverter 174, flip-flop 132, and inverter 166 provide rising edge 226 of ZCLK_P signal 208. Rising edge 226 of ZCLK_P signal 208 lags rising edge 220 of CLK signal 202 by at least one gate delay. Therefore, rising edge 224 of ZCLK_FB_P signal 206 is as much as one gate delay before rising edge 226 of ZCLK_P signal 208. In response to rising edge 224 of ZCLK_FB_P signal 206, flip-flop 134 provides falling edge 228 of P_DW signal 210 and maintains P_UP signal 212 logic high. In response to falling edge 228 of P_DW signal 210, flip-flop 136 provides rising edge 230 of DW signal 214 and falling edge 232 of UP signal 216.

Therefore, if rising edge 220 of CLK signal 202 leads rising edge 222 of FB signal 204, flip-flop 134 reacts to rising edge 224 of ZCLK_FB_P signal 206 no matter where rising edge 222 of FB signal 204 occurs within the logic high time of CLK signal 202. Rising edge 224 of ZCLK_FB_P signal 206 leads rising edge 226 of ZCLK_P signal 208 by as much as one gate delay. The logic low pulse of P_DW signal 210 starting at falling edge 228 lasts as long as the logic high time of CLK signal 202. In this way, any race condition within phase detector 108 generated between rising edge 220 of CLK signal 202 and rising edge 222 of FB signal 222 is avoided.

FIG. 4 is a timing diagram 250 illustrating another embodiment of the timing of signals for phase detector 108. Timing diagram 250 includes the same signals as timing diagram 200 including CLK signal 202 on CLK signal path 112, FB signal 204 on FB signal path 110, ZCLK_PFBP_P signal 206 on ZCLK_FB_P signal path 148, ZCLK_P signal 208 on ZCLK_P signal path 168, P_DW signal 210 on P_DW signal path 152, P_UP signal 212 on P_UP signal path 156, DW signal 214 on DW signal path 114, and UP signal 216 on UP signal path 116.

In this embodiment, rising edge 260 of CLK signal 202 lags rising edge 262 of FB signal 204. In response to rising edge 260 of CLK signal 202, inverter 174, flip-flop 132, and inverter 166 provide rising edge 266 of ZCLK_P signal 208. In response to falling edge 274 of FB signal 204, flip-flop 130 and inverter 146 provide rising edge 264 of ZCLK_FB_P signal 206. In response to rising edge 266 of ZCLK_P signal 208, flip-flop 134 provides falling edge 268 of P_UP signal 212 and maintains P_DW signal 210 logic high. In response to falling edge 268 of P_UP signal 212, flip-flop 136 provides falling edge 270 of DW signal 214 and rising edge 272 of UP signal 216.

Therefore, if rising edge 262 of FB signal 204 leads rising edge 260 of CLK signal 202, flip-flop 134 reacts to rising edge 266 of ZCLK_P signal 208 no matter where rising edge 262 of FB signal 204 occurs within the logic low time of CLK signal 202. Rising edge 266 of ZCLK_P signal 208 leads rising edge 264 of ZCLK_FB_P signal 206. The logic low pulse of P_UP signal 212 starting at falling edge 268 lasts as long as the logic high time of CLK signal 202. In this way, any race condition within phase detector 108 generated between rising edge 260 of CLK signal 202 and rising edge 262 of FB signal 204 is avoided.

Embodiments of the present invention provide a phase detector. The phase detector is easily scalable to higher operating frequencies. Even a small phase difference between the two input signals does not lead to a race condition within the phase detector. In addition, the phase detector is substantially process insensitive.

What is claimed is:

1. A phase detector comprising:
a first circuit configured to provide a first signal in response to a feedback signal and a clock signal;
a second circuit configured to provide a second signal in response to the clock signal and an inverted clock signal; and
a third circuit configured to provide a third signal indicating whether the clock signal leads the feedback signal and a fourth signal indicating whether the feedback signal leads the clock signal in response to the first signal and the second signal.

2. The phase detector of claim 1, further comprising:
a fourth circuit configured to provide a down control signal in response to the third signal and an up control signal in response to the fourth signal.

3. The phase detector of claim 2, wherein the fourth circuit comprises a flip-flop.

4. The phase detector of claim 3, wherein the flip-flop comprises a NAND flip-flop.

5. The phase detector of claim 1, wherein the first circuit comprises a first flip-flop, the second circuit comprises a second flip-flop, and the third circuit comprises a third flip-flop.

6. The phase detector of claim 5, wherein the first flip-flop comprises a NAND flip-flop, the second flip-flop comprises a NAND flip-flop, and the third flip-flop comprises a NAND flip-flop.

7. A phase detector comprising:
a first flip-flop configured to provide a third signal in response to a first signal and a second signal;
a second flip-flop configured to provide a fourth signal in response to the second signal and an inverted second signal; and
a third flip-flop configured to provide a fifth signal and a sixth signal in response to an inverted third signal and an inverted fourth signal,
wherein the fifth signal indicates whether the first signal lags the second signal and the sixth signal indicates whether the first signal leads the second signal.

8. The phase detector of claim 7, further comprising:
a fourth flip-flop configured to provide a down control signal and an up control signal in response to the fifth signal and the sixth signal.

9. The phase detector of claim 8, wherein the fourth flip-flop comprises a NAND flip-flop.

10. The phase detector of claim 7, wherein the first flip-flop comprises a NAND flip-flop, the second flip-flop comprises a NAND flip-flop, and the third flip-flop comprises a NAND flip-flop.

11. The phase detector of claim 7, wherein the first signal is a feedback signal and the second signal is a clock signal.

12. A phase detector comprising:
means for providing a first signal in response to a feedback signal and a clock signal;
means for providing a second signal in response to the clock signal and an inverted clock signal;
means for providing a down pulse in response to the first signal leading the second signal; and
means for providing an up pulse in response to the second signal leading the first signal.

13. The phase detector of claim 12, further comprising:
means for providing a down control signal in response to the down pulse; and
means for providing an up control signal in response to the up pulse.

14. A method for detecting a phase difference, the method comprising:
receiving a first signal and a second signal;
inverting the second signal to provide an inverted second signal;
providing a third signal in response to the first signal and the second signal;
providing a fourth signal in response to the second signal and the inverted second signal;
providing a fifth signal in response to the third signal leading the fourth signal; and
providing a sixth signal in response to the fourth signal leading the third signal.

15. The method of claim 14, further comprising:
providing a down control signal in response to the fifth signal; and
providing an up control signal in response to the sixth signal.

16. The method of claim 14, wherein receiving the first signal comprises receiving a feedback signal and receiving the second signal comprises receiving a clock signal.

17. The method of claim 14, wherein providing the fifth signal comprises providing a down signal pulse, and wherein providing the sixth signal comprises providing an up signal pulse.

18. A method for detecting a phase difference, the method comprising:
providing a first signal in response to a clock signal and a feedback signal;
providing a second signal in response to the clock signal and an inverted clock signal;
one of providing a down signal pulse in response to providing the first signal before providing the second signal and providing an up signal pulse in response to providing the second signal before providing the first signal.

19. The method of claim 18, further comprising:
providing a down control signal in response to the down signal pulse; and
providing an up control signal in response to the up signal pulse.

20. The method of claim 18, wherein providing the second signal comprises providing the second signal at least one gate delay after a rising edge of the clock signal.

21. An electronic system comprising:
a host; and
a memory including a phase detector configured to receive a clock signal from the host,
wherein the phase detector comprises:
a first circuit configured to provide a first signal in response to a feedback signal and the clock signal;
a second circuit configured to provide a second signal in response to the clock signal and an inverted clock signal; and
a third circuit configured to provide a third signal indicating whether the clock signal leads the feedback signal and a fourth signal indicating whether the feedback signal leads the clock signal in response to the first signal and the second signal.
